(19) United States
(12) Patent Application Publication
(10) Pub. No.: US 2026/0213496 A1
(43) Pub. Date: Jul. 23, 2026

(54) EDGE-EMITTING SEMICONDUCTOR LASER, METHOD OF MANUFACTURING A PLURALITY OF EDGE-EMITTING SEMICONDUCTOR LASERS, LASER COMPONENT AND METHOD OF MANUFACTURING A LASER COMPONENT

(71) Applicant: ams-OSRAM International GmbH, Regensburg (DE)

(72) Inventors: Sven GERHARD, Alteglofsheim (DE); Christoph EICHLER, Donaustauf (DE); Lars NAEHLE, Bad Abbach (DE)

(21) Appl. No.: 19/138,035

(22) PCT Filed: Dec. 6, 2023
(86) PCT No.: PCT/EP2023/084545

§ 371 Date: Jun. 11, 2025

(30) Foreign Application Priority Data
Dec. 12, 2022 (DE) 10 2022 133 047.8

(51) Int. Cl. H01S 5/40; H01S 5/02; H01S 5/026; H01S 5/028; H01S 5/10; H01S 5/20; H01S 5/30

(52) U.S. Cl. CPC H01S 5/4031; H01S 5/0203; H01S 5/026; H01S 5/0287; H01S 5/1082; H01S 5/2031; H01S 5/3013; H01S 5/3077; H01S 2301/166

(57) ABSTRACT

An edge emitting semiconductor laser includes an epitaxial semiconductor layer stack including a plurality of epitaxial semiconductor layers stacked on top of each other in a stacking direction. The epitaxial semiconductor layer stack includes an active zone in which electromagnetic laser radiation is generated during operation. The epitaxial semiconductor layer stack includes at least one facet laterally confining the epitaxial semiconductor layer stack. The facet includes a vertical structure in the stacking direction influencing at least one vertical mode of the electromagnetic laser radiation. The vertical structure includes at least one recess in the stacking direction. The recess is arranged between a waveguide layer of the epitaxial semiconductor layer stack and the substrate on a side of the waveguide layer facing away from the active zone. The active zone does not comprise a recess and the substrate has a protrusion with respect to the epitaxial semiconductor layer stack.

An edge-emitting semiconductor laser, a method of manufacturing a plurality of edge-emitting semiconductor lasers, a laser component and a method of manufacturing a laser component are specified.

An improved edge-emitting semiconductor laser is to be specified. In particular, an edge-emitting semiconductor laser having a long lifetime is to be provided.

Furthermore, a simplified method of manufacturing a plurality of edge-emitting semiconductor lasers, which in particular have a long lifetime, is to be specified.

Finally, an improved laser component and a simplified method of manufacturing the same are to be specified.

These objects are achieved by an edge-emitting semiconductor laser comprising the features of claim 1, by a laser component comprising the features of claim 15, by a method of manufacturing a plurality of edge-emitting semiconductor lasers comprising the steps of claim 16 and by a method of manufacturing a laser component comprising the steps of claim 20.

Advantageous embodiments and developments of the edge-emitting semiconductor laser, of the method of manufacturing a plurality of edge-emitting semiconductor lasers, of the laser component and of the method of manufacturing a laser component are specified in the respective dependent claims.

According to an embodiment, the edge-emitting semiconductor laser comprises an epitaxial semiconductor layer stack comprising a plurality of epitaxial semiconductor layers stacked on top of each other in a stacking direction. In particular, the epitaxial semiconductor layers are epitaxially grown on a growth substrate. The growth substrate can be part of the edge-emitting semiconductor laser or can be removed from the finished semiconductor laser.

In particular, the edge-emitting semiconductor laser is an edge-emitting semiconductor laser diode.

According to a further embodiment of the edge-emitting semiconductor laser, the epitaxial semiconductor layer stack comprises an active zone in which electromagnetic laser radiation is generated during operation of the edge-emitting semiconductor laser. In particular, the active zone serves as a laser medium arranged within a resonator of the edge-emitting semiconductor laser. In conjunction with the resonator, a population inversion is generated within the active zone, such that electromagnetic laser radiation is generated in the active zone by stimulated emission. On account of the generation of the electromagnetic laser radiation by stimulated emission, the electromagnetic laser radiation, in contrast to electromagnetic radiation generated by spontaneous emission, generally has a very high coherence length, a very narrow emission spectrum and/or a high degree of polarization.

According to a further embodiment of the edge-emitting semiconductor laser, the epitaxial semiconductor layer stack comprises at least one facet laterally confining the epitaxial semiconductor layer stack. The facet is in particular part of the epitaxial semiconductor layer stack. In particular, the facet entirely or partially forms a side surface of the epitaxial semiconductor layer stack. In other words, the facet is formed in particular from the semiconductor material of the semiconductor layer stack.

According to a further embodiment of the edge-emitting semiconductor laser, the semiconductor layer stack comprises a further facet. The two facets are preferably opposite each other and entirely or partially form the side surfaces of the epitaxial semiconductor layer stack. In particular, the two facets run parallel to each other. All embodiments and features which are described in the present case in connection with a facet can also be formed in both facets.

According to a further embodiment, a highly reflective layer which is formed to be highly reflective for the electromagnetic laser radiation is applied to one of the facets. Particularly preferably, a lower reflecting layer which is partially transmissive for a part of the electromagnetic laser radiation generated in the active zone is applied to the other facet. In particular, the highly reflective layer and the lower reflecting layer together form the resonator of the edge-emitting semiconductor laser. For this purpose, the highly reflective layer and the lower reflecting layer are at a distance from each other which is proportional to an integral multiple of half the wavelength of the electromagnetic laser radiation. An optical axis of the resonator is perpendicular to the facets and runs parallel to a main extension plane of the epitaxial semiconductor layers and parallel to a longitudinal direction. The longitudinal direction is perpendicular to the stacking direction. Furthermore, a lateral direction runs perpendicular to the stacking direction of the epitaxial semiconductor layers and perpendicular to the longitudinal direction.

According to an embodiment, the edge-emitting semiconductor laser comprises a radiation exit region from which the edge-emitting semiconductor laser emits electromagnetic laser radiation during operation. The radiation exit region of the edge-emitting semiconductor laser is in particular comprised by the lower reflecting layer which is partially transmissive for the electromagnetic laser radiation.

According to a further embodiment of the edge-emitting semiconductor laser, the facet comprises a vertical structure in the stacking direction influencing at least one vertical mode of the electromagnetic laser radiation and/or at least reducing a current flow in the region of the facet. In particular, the vertical structure reduces or prevents the current flow through the facet, particularly preferably in the stacking direction.

In particular, the electromagnetic laser radiation generally initially comprises different vertical, lateral and longitudinal modes. The longitudinal modes of the electromagnetic laser radiation extend in particular along the longitudinal direction, the lateral modes of the electromagnetic laser radiation extend along the lateral direction and the vertical modes of the electromagnetic laser radiation extend along the stacking direction. The vertical modes of the electromagnetic laser radiation differ in terms of wavelength, phase and/or amplitude. The lateral modes of the electromagnetic laser radiation and the longitudinal modes of the electromagnetic laser radiation also differ in terms of wavelength, phase and/or amplitude.

In particular in the case of an edge-emitting semiconductor laser having a comparatively wide vertical waveguide, the electromagnetic laser radiation generated in the resonator generally comprises a plurality of vertical modes. Therefore, in particular in the case of an edge-emitting semiconductor laser having a wide vertical waveguide, a selection of the vertical modes by a vertical structure in the stacking direction in the facet is particularly expedient. For example, the vertical waveguide has a width of between 50 nanometres and 50 micrometres inclusive, preferably between 100 nanometres and 2 micrometres inclusive. A comparatively wide vertical waveguide advantageously reduces the facet loading by the irradiation with electromagnetic laser radiation.

In particular, the vertical structure varies along the stacking direction. For example, the vertical structure is formed by recesses and/or projections in the facet which vary along the stacking direction. In particular, the vertical structure is introduced into the facet in a targeted manner rather than in a random manner. Furthermore, structural elements of the vertical structure, such as recesses and/or projections, have no random distribution in the facet. The vertical structure is configured in particular to scatter and/or attenuate undesired vertical modes, for example of a higher order, of the electromagnetic laser radiation in a targeted manner such that only one desired mode, for example the vertical fundamental mode, of the electromagnetic laser radiation is formed. Preferably, the electromagnetic laser radiation which is emitted by the radiation exit region comprises only one mode, for example the vertical fundamental mode.

According to a further embodiment of the edge-emitting semiconductor laser, the vertical structure is arranged completely or partially overlapping in the stacking direction with a radiation exit region of the edge-emitting semiconductor laser. In other words, the vertical structure is arranged in the facet which is covered with the lower reflecting layer which comprises the radiation exit region, wherein the vertical structure overlaps with the radiation exit region in a plan view of the facet. Furthermore, it is also possible that the vertical structure is arranged in the facet which is covered with the highly reflective layer and from which no electromagnetic laser radiation exits. In this case, the vertical structure is likewise arranged overlapping with the radiation exit region in a plan view of the facet.

According to a further embodiment of the edge-emitting semiconductor laser, the vertical structure comprises at least one recess in the stacking direction or is formed by a recess. In particular, the recess extends starting from the facet in the longitudinal direction into the semiconductor layer stack. In this case, the recess can extend along the entire lateral direction within the epitaxial semiconductor layer stack or also only partially. In particular, it is possible with the aid of the recess to reduce or prevent the current flow in the region of the facet in the stacking direction through the epitaxial semiconductor layer stack. Thus, damage to the facet during operation of the edge-emitting semiconductor laser by the electromagnetic laser radiation (“catastrophic optical damage”, COD for short) can at least be reduced. This extends the lifetime of the edge-emitting semiconductor laser.

According to a further embodiment of the edge-emitting semiconductor laser, the vertical structure comprises two or more recesses in the stacking direction or consists of two or more recesses having different depths in the longitudinal direction. In other words, the recesses extend to different depths in the longitudinal direction into the epitaxial semiconductor layer stack.

It is also possible for the vertical structure to comprise a plurality of recesses or to be formed from a plurality of recesses. In this case, the recesses can be formed in the same way or differently. All features and embodiments which are disclosed in the present case for a recess can also be formed in further recesses of the vertical structure.

According to a further embodiment of the edge-emitting semiconductor laser, the recess is formed by an etching of one of the epitaxial semiconductor layers starting from the facet. For example, the material of one of the epitaxial semiconductor layers of the epitaxial semiconductor layer stack is partially or entirely removed starting from the facet in a region extending in the longitudinal and/or lateral direction. For example, the etching has a depth, that is to say an extent in the longitudinal direction starting from the facet, which is between 50 nanometres and 30 micrometres inclusive or between 100 nanometres and 5 micrometres inclusive or between 500 nanometres and 2 micrometres inclusive.

According to a further embodiment of the edge-emitting semiconductor laser, the epitaxial semiconductor layers of the epitaxial semiconductor layer stack comprise a III/V compound semiconductor material according to the formula InₓAl_{y}Ga_{1-x-y}GV with 0≤x≤1, 0≤y≤1 and x+y≤1 or are formed from such a III/V compound semiconductor material, wherein GV is an element of the fifth main group of the periodic table. In particular, GV is Al, In or Ga. Preferably, the epitaxial semiconductor layer with the etching comprises a higher aluminum content and/or a higher indium content than at least one of the directly adjacent epitaxial semiconductor layers. In particular, a variation of the aluminum content and/or of the indium content enables a selective etching of one of the epitaxial semiconductor layers with respect to at least one directly adjacent epitaxial semiconductor layer of the epitaxial semiconductor layer stack.

According to an embodiment of the edge-emitting semiconductor laser, the epitaxial semiconductor layer with the etching comprises a different, preferably a higher, doping than at least one of the directly adjacent epitaxial semiconductor layers of the epitaxial semiconductor layer stack. Due to the different, preferably higher, doping, the epitaxial semiconductor layer preferably comprises a higher etching rate with respect to an etching medium than at least one of the directly adjacent epitaxial semiconductor layers, so that a selective etching is possible. For example, the epitaxial semiconductor layer with the etching comprises a doping of at least 2*10¹⁸ cm⁻³ or of at least 10¹⁹cm⁻³, while at least one of the directly adjacent epitaxial semiconductor layers comprises a doping of at most 10¹⁸ cm⁻³. Particularly preferably, the epitaxial semiconductor layer with the higher doping is an n-doped epitaxial semiconductor layer.

According to an embodiment of the edge-emitting semiconductor laser, the epitaxial semiconductor layer with the etching is n-doped and comprises a higher doping than at least one of the directly adjacent epitaxial semiconductor layers.

For example, the recess is arranged in an n-doped cladding layer of the epitaxial semiconductor layer stack. In particular, the epitaxial semiconductor layer with the etching, which forms the recess, is arranged in the n-doped cladding layer of the epitaxial semiconductor layer stack. Thus, the recess is at a distance from the active zone in the stacking direction which is sufficient not to damage the active zone during the etching of the epitaxial semiconductor layer and nevertheless to influence the vertical modes, in particular of a higher order, in a targeted manner.

Generally, the epitaxial semiconductor layer stack comprises two waveguide layers, namely a p-doped waveguide layer and an n-doped waveguide layer, between which the active zone is arranged. The waveguide layers are configured to guide the electromagnetic laser radiation within the resonator.

According to a further embodiment of the edge-emitting semiconductor laser, the recess is arranged between a waveguide layer of the epitaxial semiconductor layer stack and a substrate of the edge-emitting semiconductor laser. For example, the substrate is the growth substrate of the epitaxial semiconductor layer stack.

According to a further embodiment of the edge-emitting semiconductor laser, the recess is arranged between a waveguide layer of the epitaxial semiconductor layer stack and an electrical contact layer of the edge-emitting semiconductor laser. The electrical contact layer is configured in particular to impress a current into the active zone. Preferably, the electrical contact layer is arranged on or at a main surface of the epitaxial semiconductor layer stack that faces away from the substrate. The electrical contact layer can comprise a highly doped semiconductor material or be formed from a highly doped semiconductor material and be part of the epitaxial layer stack. Furthermore, it is also possible for the electrical contact layer to comprise a transparent conductive oxide (“TCO” for short), such as indium tin oxide (“ITO” for short) or to be formed from such a material. The electrical contact layer is in particular p-doped.

According to a further embodiment of the edge-emitting semiconductor laser, the recess is arranged in a waveguide layer of the epitaxial semiconductor layer stack, preferably in an n-doped waveguide layer.

In particular, the recess is at a comparatively large distance from the active zone in the stacking direction. For example, the recess is at a distance of at least 100 nanometres, preferably at least 200 nanometres, particularly preferably at least 500 nanometres from the active zone. The recess is arranged on a side of the waveguide layer facing away from the active zone.

According to a further embodiment of the edge-emitting semiconductor laser, the facet is free of a current flow during operation of the edge-emitting semiconductor laser. Thus, the facet is protected from damage during operation. The interruption of the current flow takes place in particular through the recess.

According to a further embodiment of the edge-emitting semiconductor laser, the recess is confined in the lateral direction. In other words, the recess does not extend completely in the lateral direction in a plan view of the main surface of the epitaxial semiconductor layer stack. If the recess is confined in the lateral direction, the facet has a lateral structure along the lateral direction. Thus, lateral modes of the electromagnetic laser radiation can also be influenced in a targeted manner in the lateral direction. In particular, it is also possible in this embodiment for the recess to have a variable width in the longitudinal direction in a plan view of the main surface of the epitaxial layer stack. If the geometry of the recess varies in the longitudinal direction, the facet also has a longitudinal structure along the longitudinal direction. Thus, longitudinal modes of the electromagnetic laser radiation can also be influenced in a targeted manner in the longitudinal direction.

According to a further embodiment of the edge-emitting semiconductor laser, the recess is completely or partially filled with a porous semiconductor material. For example, the porous semiconductor material is the semiconductor material of the etched epitaxial semiconductor layer. In other words, the recess of the epitaxial semiconductor layer is preferably not first completely freely etched and subsequently filled with the porous semiconductor material; rather, the porous semiconductor material is produced during the production of the recess. For example, the recess is produced by an etching process and set in such a way that the porous semiconductor material is produced.

According to a further embodiment, the edge-emitting semiconductor laser comprises a ridge waveguide. The ridge waveguide is generally formed by a protrusion in the main surface of the epitaxial semiconductor layer stack that faces away from the substrate. The ridge waveguide is configured to guide the electromagnetic laser radiation within the epitaxial semiconductor layer stack. Generally, therefore, the radiation exit region of the edge-emitting semiconductor laser is also arranged below the ridge waveguide along the stacking direction.

According to a further embodiment, the edge-emitting semiconductor laser is an index-guided edge-emitting semiconductor laser that is free of a ridge waveguide.

The edge-emitting semiconductor laser is in particular suitable for use in a laser component. The laser component in particular comprises at least two edge-emitting semiconductor lasers. Features and embodiments which are disclosed in the present case in connection with the edge-emitting semiconductor laser can also be formed in the laser component and vice versa.

In particular, the edge-emitting semiconductor lasers of a laser component can be formed differently from one another or in the same way. For example, the edge-emitting semiconductor lasers of a laser component at least partially emit electromagnetic laser radiation different from one another. In particular, the electromagnetic laser radiation of the edge-emitting semiconductor lasers can have different wavelengths. Furthermore, it is possible for the edge-emitting semiconductor lasers to have identical or different vertical structures of the facet in the stacking direction.

A plurality of edge-emitting semiconductor lasers can be manufactured using the method described below. Features and embodiments which are described in the present case in connection with the edge-emitting semiconductor laser can also be formed in the method and vice versa.

According to an embodiment of the method of manufacturing a plurality of edge-emitting semiconductor lasers, an epitaxial semiconductor layer sequence is provided which comprises a plurality of epitaxial semiconductor layers stacked on top of each other in a stacking direction. The epitaxial semiconductor layer sequence comprises an active region in which electromagnetic radiation is generated during operation.

According to a further embodiment of the method, one or more trenches are generated in the epitaxial semiconductor layer sequence. In particular, a side surface of a trench at least partially forms a facet of a finished edge-emitting semiconductor laser.

For example, the trenches in the epitaxial semiconductor layer sequence are generated using a dry etching method in which the side surfaces of the trenches are generally initially formed tilted with respect to the stacking direction. Furthermore, the side surfaces of the trenches are generally initially formed rough after the dry etching method. The dry etching method is, for example, a plasma etching method or reactive ion etching (“RIE” for short).

According to a further embodiment of the method, vertical structures are generated in the side surfaces of the trenches in the stacking direction. In particular, the vertical structures are structures having a variation in the stacking direction.

According to a further embodiment of the method, the vertical structures in the side surfaces of the trenches are recesses formed by selectively etching at least one epitaxial semiconductor layer starting from the side surfaces of the trenches. In particular, at least one or precisely one epitaxial semiconductor layer of the epitaxial semiconductor layer sequence is etched starting from the side surfaces of the trenches in the longitudinal and/or lateral direction, such that the semiconductor material of the etched epitaxial semiconductor layer is removed or formed porously. This is possible in particular when the epitaxial semiconductor layer to be etched comprises a higher etching rate with respect to an etching medium than at least one epitaxial semiconductor layer directly adjacent to the epitaxial semiconductor layer to be etched. For example, the epitaxial semiconductor layer to be etched comprises a higher aluminum and/or indium content and/or a higher doping compared to at least one directly adjacent epitaxial semiconductor layer. A selectivity with respect to an etching medium can be generated by the differences in the aluminum content, in the indium content and/or in the doping.

The selective etching of the at least one epitaxial semiconductor layer takes place in particular by wet-chemical etching. In this case, for example, one or more of the following materials can be used as liquid, etching medium: KOH, TMAH (tetramethylammonium hydroxide), NH₃, NaOH.

In particular, the method of manufacturing a plurality of edge-emitting semiconductor lasers has the advantage that a lithographic mask for forming the vertical structure can be dispensed with. Rather, the vertical structure is achieved by different etching rates of the different epitaxial semiconductor layers with respect to an etching medium. Thus, in particular, very small vertical structures can be generated and positioned in a targeted manner in the facet, the dimensions of which in the stacking direction are predetermined by the thickness of the epitaxial semiconductor layers. The epitaxial semiconductor layers have a thickness of one atomic layer up to several micrometres. For example, the thickness of the epitaxial semiconductor layers is between 1 nanometre and 10 micrometres inclusive or between 20 nanometres and 1 micrometre inclusive.

According to a further embodiment of the method, an electrical voltage is applied to the epitaxial semiconductor layer sequence during the selective etching of at least one of the epitaxial semiconductor layers. For example, the electrical voltage has a value of between 0.5 volts and 25 volts inclusive or between 1 volts and 10 volts inclusive. In particular, the electrical voltage is applied only to partial regions of the epitaxial semiconductor layer sequence, for example by metallic contacts being applied only to partial surfaces of the ridge waveguide and/or a main surface of the epitaxial semiconductor layer sequence. Thus, current can flow through only partial regions of the epitaxial semiconductor layer sequence during the etching, so that the etching is increased by the current flow. Thus, in addition to a vertical structure in the stacking direction, a lateral structure in the lateral direction and/or a longitudinal structure in the longitudinal direction can also be generated starting from the facet.

According to a further embodiment of the method, partial regions of the epitaxial semiconductor layer sequence are irradiated with electromagnetic radiation during the selective etching of the at least one epitaxial semiconductor layer. In particular, the electromagnetic radiation with which partial regions of the epitaxial semiconductor layer sequence are irradiated has an energy which is greater than an electronic band gap of the epitaxial semiconductor layer to be etched. Thus, charge carriers which locally increase the etching rate are generated in the irradiated regions during the irradiation with the electromagnetic radiation. Thus, in addition to a vertical structure in the stacking direction, a lateral structure in the lateral direction and/or a longitudinal structure in the longitudinal direction can also be generated starting from the facet.

The method of manufacturing a plurality of edge-emitting semiconductor lasers preferably takes place at the wafer level. This means that the epitaxial semiconductor layer sequence is part of a wafer composite or is formed as a wafer composite and the plurality of edge-emitting semiconductor lasers are manufactured simultaneously. This simplifies the manufacturing process.

At the end of the method, the edge-emitting semiconductor lasers are singulated, for example by scribing and breaking, stealth dicing or laser separation. In particular, the trenches in the epitaxial semiconductor layer sequence define separation lines along which the semiconductor lasers are singulated.

During the singulation, the edge-emitting semiconductor lasers with the epitaxial semiconductor layer stacks and the active zone are produced. The epitaxial semiconductor layer stacks of the different edge-emitting semiconductor lasers are part of the active semiconductor layer sequence at the wafer level, and the active zones are part of the active region at the wafer level. Features and embodiments which are described in the present case in connection with the epitaxial semiconductor layer stack and the active zone can consequently also be formed in the epitaxial semiconductor layer sequence and the active region and vice versa.

A method of manufacturing a laser component comprising at least two edge-emitting semiconductor lasers is described below. Features and embodiments which are described in the present case in connection with the method of manufacturing a plurality of edge-emitting semiconductor lasers can also be formed in the method of manufacturing the laser component and vice versa.

According to an embodiment of the method of manufacturing a laser component, a wafer composite comprising a plurality of edge-emitting semiconductor lasers is provided. The edge-emitting semiconductor lasers of the wafer composite are formed, for example, as already described.

According to a further embodiment of the method, the wafer composite is singulated into separated laser components, for example by breaking and scribing, in particular along the trenches. Each laser component comprises at least two edge-emitting semiconductor lasers after the singulation. The edge-emitting semiconductor lasers comprise epitaxial semiconductor layer stacks laterally confined by facets. Furthermore, the epitaxial semiconductor layer stacks comprise a plurality of epitaxial semiconductor layers stacked on top of each other in a stacking direction.

According to a further embodiment of the method, vertical structures are generated in the facets of the edge-emitting semiconductor lasers in a stacking direction.

According to a further embodiment of the method, the vertical structures in the facets are recesses formed by selectively etching at least one epitaxial semiconductor layer starting from the facet.

According to a further embodiment of the method, an electrical voltage is applied to the epitaxial semiconductor layer stacks during the selective etching and/or at least partial regions of the epitaxial semiconductor layer stacks are irradiated with electromagnetic radiation.

In other words, it is possible that, in order to manufacture a laser component comprising at least two edge-emitting semiconductor lasers, the laser components are first singulated completely from the wafer composite, for instance by scribing and breaking, and subsequently the facets of the edge-emitting semiconductor lasers of the laser component are provided with a vertical structure in the stacking direction by the method already described.

The edge-emitting semiconductor laser described in the present case and/or the laser component described here can be used, for example, in AR devices (AR: abbreviated for “augmented reality”), VR devices (VR: abbreviated for “virtual reality”), projection devices, laser illuminations, devices for material processing and/or devices for distance measurement, for example with LIDAR (abbreviated for “light detection and ranging” or “light imaging, detection and ranging”).

Further advantageous embodiments and developments of the edge-emitting semiconductor laser, of the method of manufacturing a plurality of edge-emitting semiconductor lasers, of the laser component and of the method of manufacturing a laser component emerge from the example embodiments described below in connection with the figures.

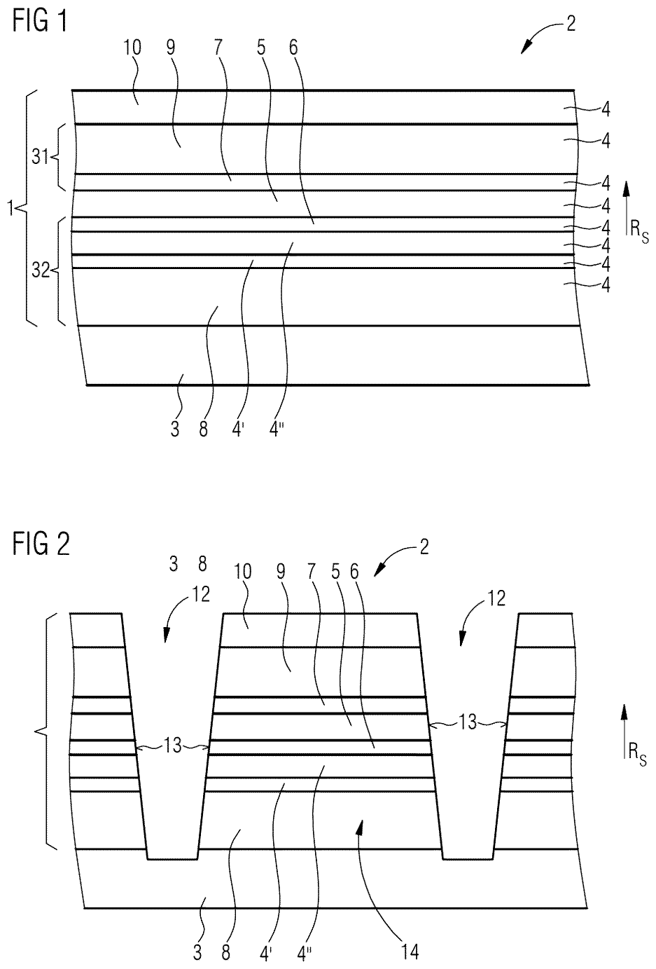

FIGS. 1 to 3 show schematic illustrations of stages of a method of manufacturing a plurality of edge-emitting semiconductor lasers according to an example embodiment.

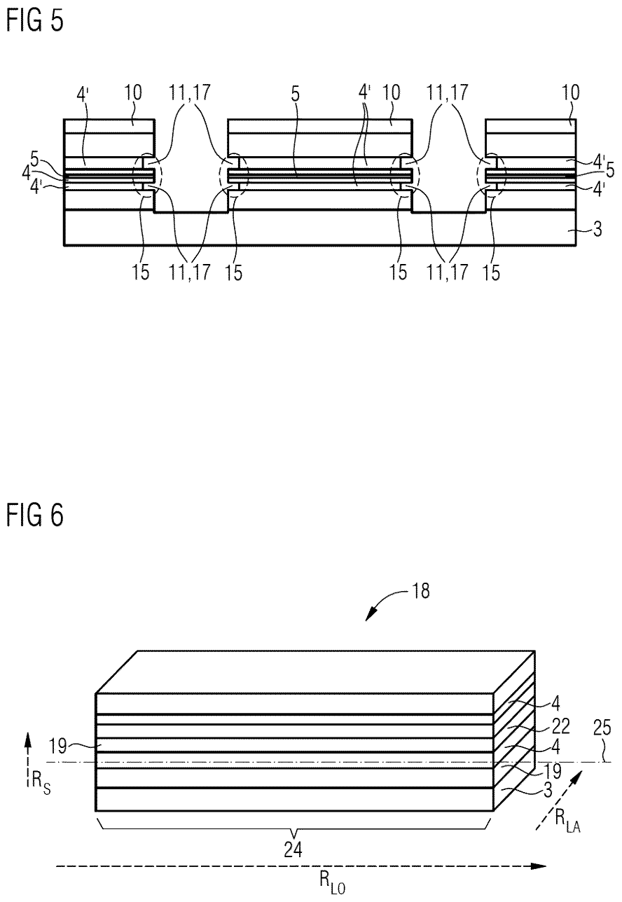

FIGS. 4 to 5 show schematic illustrations of stages of a method of manufacturing a plurality of edge-emitting semiconductor lasers according to a further example embodiment.

FIGS. 6 to 8 show schematic illustrations of an edge-emitting semiconductor laser according to an example embodiment.

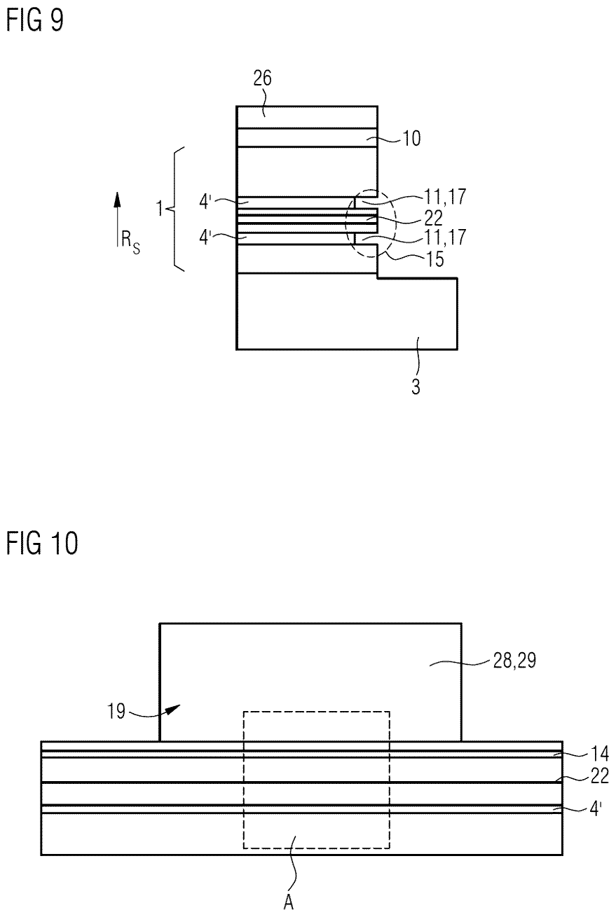

FIGS. 9 to 11 show schematic illustrations of an edge-emitting semiconductor laser according to a further example embodiment.

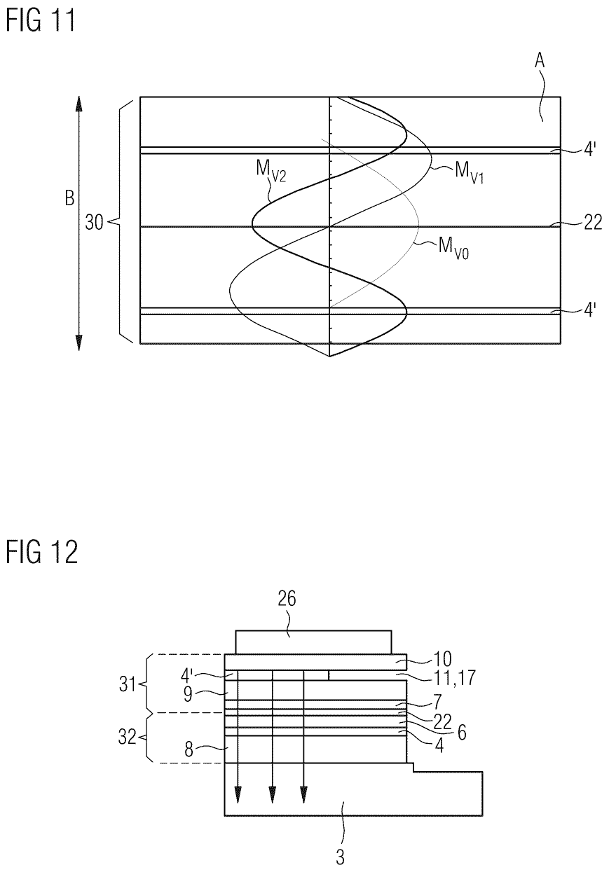

FIGS. 12 to 16 show schematic details of an edge-emitting semiconductor laser according to further example embodiments.

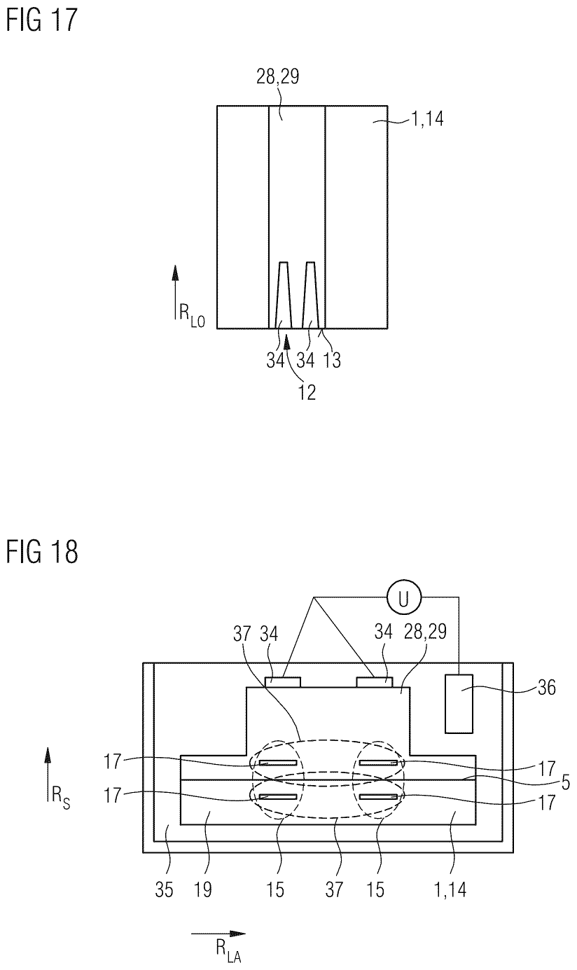

FIGS. 17 and 18 show schematic illustrations of stages of a method of manufacturing a plurality of edge-emitting semiconductor lasers according to a further example embodiment.

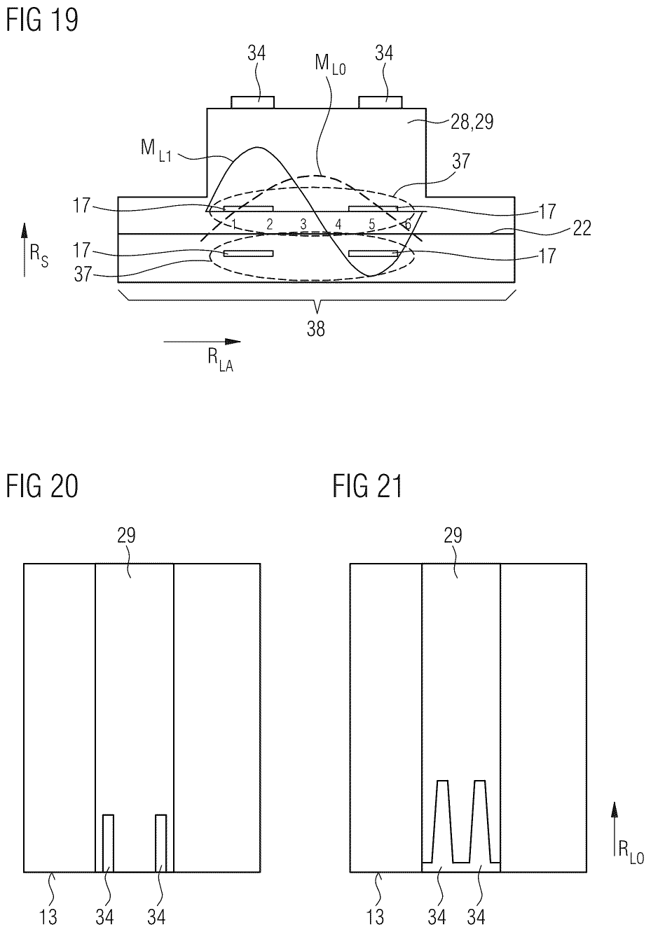

FIG. 19 shows a schematic illustration of an edge-emitting semiconductor laser according to a further example embodiment.

FIGS. 20 and 21 show embodiments of metallic contacts, as can be used in the method according to the example embodiment of FIGS. 17 and 18.

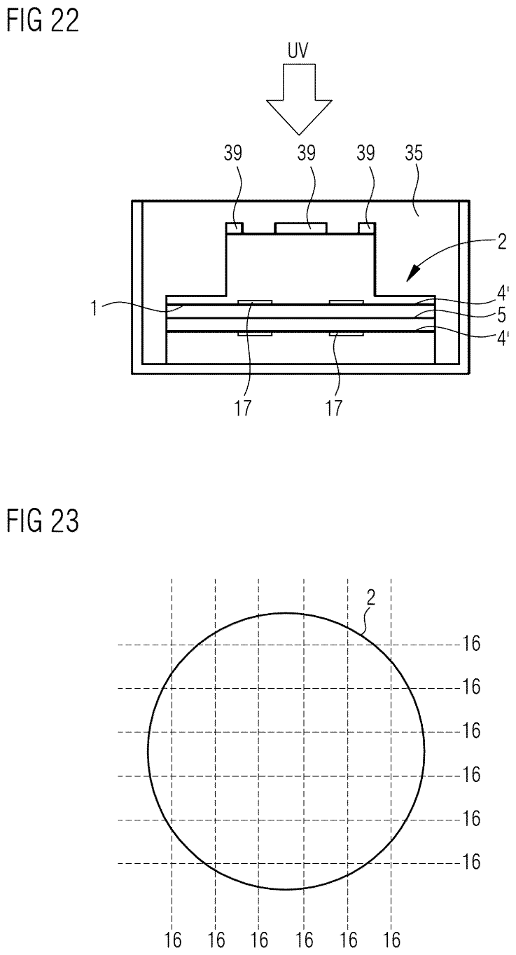

FIG. 22 shows a schematic illustration of a stage of a method of manufacturing a plurality of edge-emitting semiconductor lasers according to a further example embodiment.

FIGS. 23 to 25 show schematic illustrations of stages of a method of manufacturing a laser component according to an example embodiment.

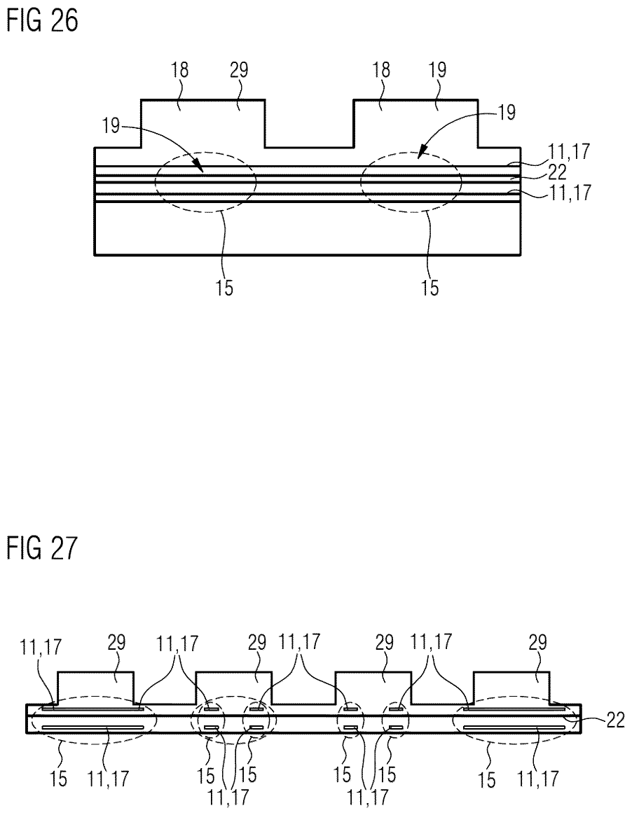

FIGS. 26 and 27 show schematic illustrations of a laser component according to different example embodiments.

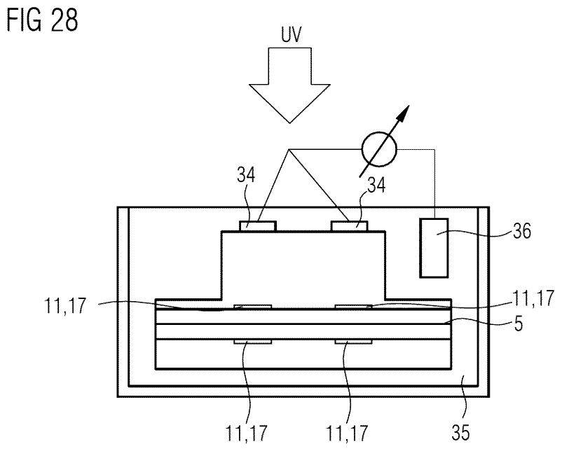

FIG. 28 shows a schematic illustration of a stage of a method of manufacturing a plurality of edge-emitting semiconductor lasers according to a further example embodiment.

Identical, similar or identically acting elements are provided with the same reference signs in the figures. The figures and the size ratios of the elements illustrated in the figures with respect to one another are not to be regarded as to scale. Rather, individual elements, in particular layer thicknesses, can be illustrated with an exaggerated size for better illustration and/or for better comprehension.

In the method of manufacturing a plurality of edge-emitting semiconductor lasers according to the example embodiment of FIGS. 1 to 3, first an epitaxial semiconductor layer sequence 1 is provided which is part of a wafer composite 2 (FIG. 1). The wafer composite 2 comprises, in addition to the epitaxial semiconductor layer sequence 1, a substrate 3 which is, for example, a growth substrate on which the epitaxial semiconductor layer sequence 1 is epitaxially grown.

The epitaxial semiconductor layer sequence 1 comprises a plurality of epitaxial semiconductor layers 4 stacked on top of each other in a stacking direction R_{S}. In particular, the epitaxial semiconductor layer sequence 1 comprises an active region 5 in which electromagnetic radiation is generated during operation.

The active region 5 is arranged between an n-doped waveguide layer 6 and a p-doped waveguide layer 7 which in the present case directly adjoin the active region 5. In addition, the epitaxial semiconductor layer sequence 1 in the present case comprises an n-doped cladding layer 8 and a p-doped cladding layer 9 between which the n-doped waveguide layer 6, the p-doped waveguide layer 7 and the active region 5 are arranged. Furthermore, the epitaxial semiconductor layer sequence 1 comprises a highly p-doped electrical contact layer 10 arranged at a main surface of the epitaxial semiconductor layer sequence 1 facing away from the substrate 3.

The n-doped cladding layer 8 and the n-doped waveguide layer 6 are part of an n-doped region 32 of the epitaxial semiconductor layer sequence 1, while the p-doped cladding layer 9 and the p-doped waveguide layer 7 are part of a p-doped region 31 of the epitaxial semiconductor layer sequence 1.

Finally, the epitaxial semiconductor layer sequence 1 comprises an epitaxial semiconductor layer 4′ which in the present case is arranged between the n-doped waveguide layer 6 and the n-doped cladding layer 8 and which is configured to be provided with a recess 11 by selective etching against a directly adjacent epitaxial semiconductor layer 4″. The epitaxial semiconductor layer 4′ to be etched is located in the n-doped region 32 of the epitaxial semiconductor layer sequence 1.

In a next step which is illustrated schematically in FIG. 2, a plurality of trenches 12 is generated in the epitaxial semiconductor layer sequence 1. In the present case, however, only two trenches 12 are illustrated for reasons of clarity. In particular, the trenches 12 completely penetrate the epitaxial semiconductor layer sequence 1 and partially penetrate the substrate 3. The trenches 12 are in the present case generated by a dry etching method and have oblique side surfaces 13 which are arranged tilted with respect to the stacking direction R_{S}. Furthermore, the side surfaces 13 of the trenches 12 are formed rough. By introducing the trenches 12, epitaxial semiconductor layer stacks 14 are defined which are arranged between two directly adjacent trenches 12 and are confined by the side surfaces 13 thereof.

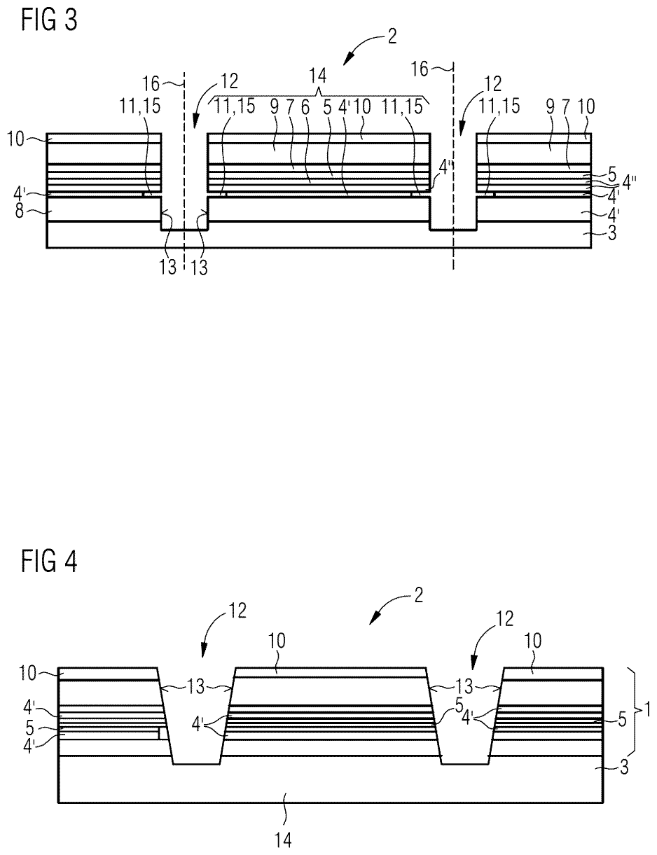

In a next step, vertical structures 15 are generated in the side surfaces 13 of the trenches 12 in the stacking direction R_{S} (FIG. 3). In particular, by wet-chemical etching, recesses 11 are generated in the epitaxial semiconductor layer sequence 1 starting from the side surfaces 13 of the trenches 12. In the present case, the recesses 11 are generated by wet-chemical selective etching with an alkaline etching medium, such as, for example, KOH, TMAH, NH₃ and/or NaOH, in the epitaxial semiconductor layer 4′ to be etched. The epitaxial semiconductor layer 4′ to be etched comprises a higher etching rate with respect to the alkaline etching medium compared to the directly adjacent epitaxial semiconductor layer 4″, which in the present case serves as an etch stop layer, for example due to a higher aluminum content and/or a higher indium content and/or a higher doping. For example, the recesses 11 are arranged on a side of the cladding layer 6 facing away from the active region 5. The side surfaces 13 of the trenches 12 are furthermore formed perpendicular by the wet-chemical etching with the alkaline etching medium.

Finally, the edge-emitting semiconductor lasers are singulated (not illustrated) along separation lines 16 which run in the trenches 12.

In the method according to the example embodiment of FIGS. 4 and 5, the structure of the epitaxial semiconductor layer sequence 1 differs from the structure of the epitaxial semiconductor layer sequence 1 according to the example embodiment of FIGS. 1 to 3. In particular, the epitaxial semiconductor layer sequence 1 comprises two epitaxial semiconductor layers 4′, into which etchings 17 are to be introduced as recesses 11 by selective etching.

First, as already described with reference to FIG. 2, a plurality of trenches 12 are introduced into the epitaxial semiconductor layer sequence 1 using a dry etching process (FIG. 4).

As already described with reference to FIG. 3, a wet-chemical etching is then carried out using a liquid etching medium, wherein the epitaxial semiconductor layers 4′ to be etched are etched selectively with respect to at least one directly adjacent epitaxial semiconductor layer 4, such that etchings 17 form as recesses 11 starting from the side surfaces 13 of the trenches 12 in the epitaxial semiconductor layer stacks 14. In the present case, the epitaxial semiconductor layers 4′ to be etched are formed in the same way, such that the recesses 11 also form in the same way in the epitaxial semiconductor layer stacks 14 (FIG. 5).

The edge-emitting semiconductor laser 18 according to the example embodiment of FIGS. 6 to 8 can be generated, for example, using the method according to FIGS. 1 to 3.

The edge-emitting semiconductor laser 18 according to the example embodiment of FIGS. 6 to 8 comprises an epitaxial semiconductor layer stack 14 comprising a plurality of epitaxial semiconductor layers 4 stacked on top of each other in a stacking direction RS. The epitaxial semiconductor layer stack 14 is laterally confined by facets 19 which are opposite each other and run parallel to each other. The epitaxial semiconductor layer stack 14 furthermore comprises an active zone 22 in which electromagnetic laser radiation L is generated during operation of the edge-emitting semiconductor laser 18.

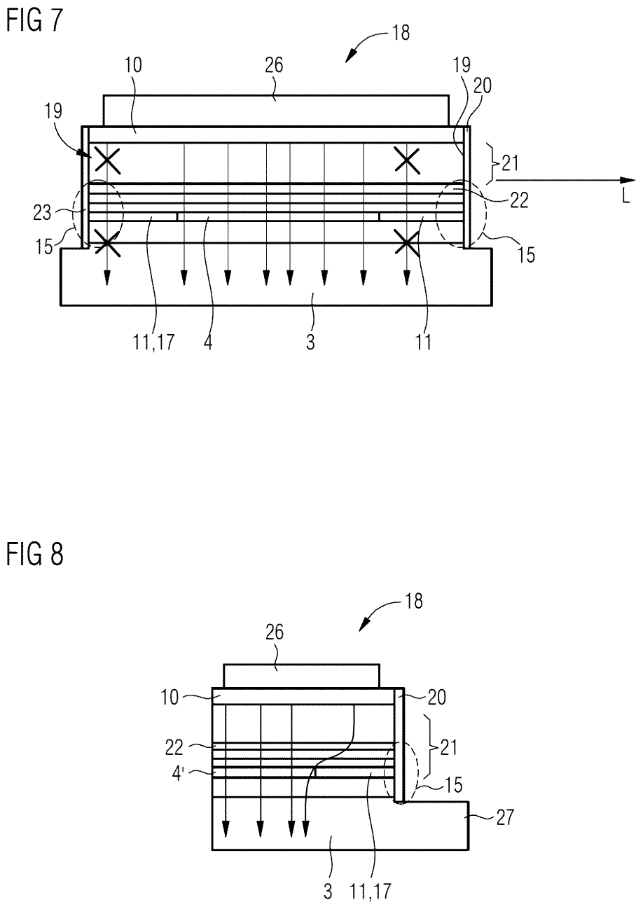

Furthermore, a lower reflecting layer 20 which is partially transmissive for the electromagnetic laser radiation is applied to one facet 19. Therefore, electromagnetic laser radiation L is coupled out of a radiation exit region 21 from this facet 19 during operation of the edge-emitting semiconductor laser 18 (FIGS. 7 and 8).

Furthermore, a highly reflective layer 23 which is highly reflective for the electromagnetic laser radiation L of the active zone 22 is formed on the opposite facet 19. The highly reflective layer 23 on one facet 19 and the lower reflecting layer 20 on the other facet 19 in the present case form a resonator 24 of the edge-emitting semiconductor laser 18. An optical axis 25 of the resonator 24 extends along a longitudinal direction R_{LO}. A lateral direction RLA extends perpendicular to the longitudinal direction R_{LO} and to the stacking direction R_{S} (FIG. 6).

As shown by way of example in FIG. 7, the facets 19 comprise a vertical structure 15 in the stacking direction R_{S}. In particular, the vertical structure 15 in the present case is formed by a recess 11 which extends starting from the facet 19 into the epitaxial semiconductor layer stack 14. In the present case, the recess 11 is formed by etching one of the epitaxial semiconductor layers 4′ of the epitaxial semiconductor layer stack 14.

The edge-emitting semiconductor laser 18 according to FIGS. 6 to 8 comprises a metallic contact layer 26 on the electrical contact layer 10, which is configured to impress a current into the edge-emitting semiconductor laser 18 and in particular into the active zone 5. For this purpose, a further metallic contact layer which is not illustrated in the present case for reasons of clarity is applied to a rear main surface of the substrate 3.

FIG. 8 shows a detail of the epitaxial semiconductor layer stack 14 with one of the facets 19. As the arrows make clear, the epitaxial semiconductor layer 4′ with the etching 17 delimits or confines the current flow through the active zone 5. A crystal of the epitaxial semiconductor layer stack 14 is interrupted at the facet 19, so that in particular non-radiative recombination centers are arranged there. The non-radiative recombination centers generate heat during operation during current flow, which promotes damage to the facet 19 by COD.

Furthermore, the metallic contact layer 26 which is applied to the main surface of the epitaxial semiconductor layer stack 14 facing away from the substrate 3 is arranged set back from the two facets 19. In this way, the current flow can also be at least reduced in regions of the epitaxial semiconductor layer stack 14 close to the facets. However, it is also possible for the metallic contact layer 26 to directly adjoin the facets 19, since the current flow is already correspondingly prevented through the recess 11. In this way, structuring of the metallic contact layer 26 can advantageously be dispensed with.

As can be seen in FIGS. 7 and 8, the substrate 3 comprises a protrusion 27 opposite the epitaxial semiconductor layer stack 14. In particular, the facet 19 is formed by the plasma etching process and the subsequent wet-chemical process, while complete separation within the trenches 12 takes place by a further separation process, for instance mechanical breaking. As a result, the protrusion 27 generally forms in the substrate 3.

The edge-emitting semiconductor laser 18 according to the example embodiment of FIGS. 9 to 11 can be generated, for example, using the method according to FIGS. 4 and 5.

The edge-emitting semiconductor laser 18 comprises an active zone 22 arranged between two epitaxial semiconductor layers 4′ provided with recesses 11, starting from a facet 19, in the longitudinal direction RLO in the epitaxial semiconductor layer stack 14. A vertical structure 15 is formed by the recesses 11 in the facet 19 in the stacking direction R_{S} (FIG. 9).

The edge-emitting semiconductor laser 18 according to the example embodiment of FIGS. 9 to 11 furthermore comprises a ridge waveguide 28 formed by a protrusion 29 in the epitaxial semiconductor layer stack 14. In particular, FIG. 10 shows a schematic plan view of the facet 19 of the edge-emitting semiconductor laser 18 with the ridge waveguide 28.

FIG. 11 shows the detail A marked by a dashed rectangle in FIG. 10. In particular, the formation of vertical modes of the electromagnetic laser radiation L is shown schematically in FIG. 11.

FIG. 11 shows the profile of the zero order vertical mode M_{V0} (vertical fundamental mode) of the electromagnetic laser radiation L, the first order vertical mode M_{V1} of the electromagnetic laser radiation L and the second order vertical mode M_{V2} of the electromagnetic laser radiation L in a vertical waveguide 30 of width B. In this case, the vertical fundamental mode M_{V0} is amplified in the vertical waveguide 30 since the minimum of the vertical fundamental mode M_{V0} overlaps with the etched epitaxial semiconductor layers 4′ and the maximum of the vertical fundamental mode M_{V0} overlaps with the active zone 22.

Furthermore, the first order vertical mode M_{V1} of the electromagnetic laser radiation L has a minimum in the active zone 22 such that the first order vertical mode M_{V1} is not amplified during operation of the edge-emitting semiconductor laser 18.

However, the second order vertical mode M_{V2} has a maximum in the active zone 22 such that the second order vertical mode M_{V2} would be amplified without further measures. However, since a further maximum of the second order vertical mode MV2 overlaps with the etched epitaxial semiconductor layer 4′, the second order vertical mode MV2 experiences strong scattering losses in this region and is thus attenuated. Thus, a comparatively wide vertical waveguide 30 can be realized in the case of the edge-emitting semiconductor laser 18 and nevertheless it is possible that only the vertical fundamental mode M_{V0} of the electromagnetic laser radiation L is formed during operation of the edge-emitting semiconductor laser 18 on account of the vertical structure 15 in the facet 19.

In the case of the edge-emitting semiconductor lasers 18 according to the example embodiments of FIGS. 12 to 16, in particular the vertical structures 15 differ in the facet 19 along the stacking direction R_{S}.

In the case of the edge-emitting semiconductor laser 18 according to the example embodiment of FIG. 12, the epitaxial semiconductor layer 4′ with the etching 17 is arranged in a p-doped region 31 of the epitaxial semiconductor layer stack 14. In particular, the epitaxial semiconductor layer 4′ with the etching 17 is arranged between a highly p-doped electrical contact layer 10 and a p-doped cladding layer 9. In this way, as symbolized by the arrows, a current flow can also be at least reduced in the region of the facet 19 in order to at least reduce a loading of the facet 19 with electromagnetic laser radiation L during the operation of the edge-emitting semiconductor laser 18.

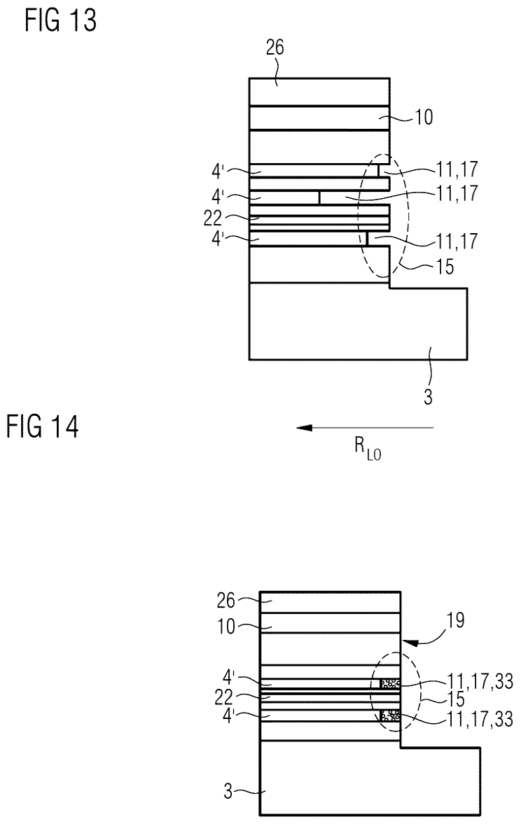

In the case of the edge-emitting semiconductor laser 18 according to the example embodiment of FIG. 13, a plurality of epitaxial semiconductor layers 4′ of the epitaxial semiconductor layer stack 14 are provided with a recess 11, in particular an etching 17, starting from a facet 19 of the edge-emitting semiconductor laser 18. The recesses 11 extend to different depths along a longitudinal direction R_{LO} into the epitaxial semiconductor layer stack 14.

In the case of the edge-emitting semiconductor laser 18 according to FIG. 14, the epitaxial semiconductor layer sequence 1 is formed before the etching, as already described with reference to FIGS. 4 and 5. In contrast to the methods according to the example embodiment of FIGS. 4 and 5, however, the etching process for forming the etchings 17 in the epitaxial semiconductor layers 4′ to be etched is changed, such that the semiconductor material of the epitaxial semiconductor layers 4′ to be etched is not completely removed, but rather is formed porously. Consequently, the recess 11 is filled with a porous material 33.

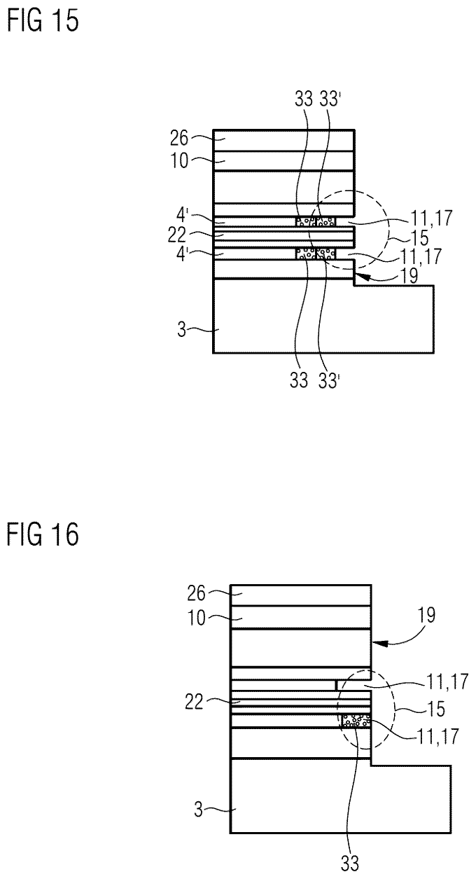

In contrast to the edge-emitting semiconductor laser 18 according to the example embodiment of FIG. 14, the edge-emitting semiconductor laser 18 according to the example embodiment of FIG. 15 has etchings 17 which are only partially filled with a porous semiconductor material 33. In particular, the recesses 11 are filled with different porous semiconductor materials 33, 33′. The recesses 11 of the epitaxial semiconductor layers 4′ according to FIG. 14 comprise in particular two different porous semiconductor materials 33, 33′. Furthermore, the recesses 11 are not completely filled with the porous semiconductor materials 33, 33′. This can be achieved by a further modification of the etching process.

The edge-emitting semiconductor laser 18 according to the example embodiment of FIG. 16 likewise comprises two etched epitaxial semiconductor layers 4′ having recesses 11 starting from the facet 19. In this case, the etched epitaxial semiconductor layers 4′ differ in terms of their material composition. Therefore, the one recess 11 is filled with a porous semiconductor material 33 which was produced in that the recess 11 was not completely etched free, but rather in that the semiconductor material of the epitaxial semiconductor layer 4′ was only partially porosified by the etching process. However, the other epitaxial semiconductor layer 4′ has an empty recess 11.

In the method of manufacturing a plurality of edge-emitting semiconductor lasers according to the example embodiment of FIGS. 17 to 18, in turn an epitaxial semiconductor layer sequence 1 is provided which comprises a plurality of epitaxial semiconductor layers 4. Furthermore, the epitaxial semiconductor layer sequence 1 comprises a plurality of epitaxial semiconductor layer stacks 14, wherein each epitaxial semiconductor layer stack 14 has a protrusion 29 which forms a ridge waveguide 29 in the finished semiconductor laser 18. In the present case, only one epitaxial semiconductor layer stack 14 is shown in the figures for reasons of clarity. However, the epitaxial semiconductor layer sequence 1 comprises a plurality of epitaxial semiconductor layer stacks 14 separated from each other by trenches 12.

Two metallic contacts 34 are applied to the protrusion 29 and extend starting from a side surface 13 of the trench 12 along the longitudinal direction R_{LO} on the protrusion 29 (FIG. 17).

The epitaxial semiconductor layer sequence 1 comprising the trenches 12 and the metallic contacts 34 on the protrusions 29 are introduced into an alkaline etching medium 35 in a next step which is illustrated schematically in FIG. 18. In this case, a voltage U is applied between the metallic contacts 34 on the protrusion 29 and an electrode 36 in the alkaline etching medium 35. Due to the applied voltage U, a current flow takes place through the epitaxial semiconductor layer stacks 14 of the epitaxial semiconductor layer sequence 1 during the wet-chemical selective etching of at least one epitaxial semiconductor layer 4′, so that the epitaxial semiconductor layer 4′ to be etched is etched only in the region of the metallic contacts 34. Thus, in addition to a vertical structure 15 in the stacking direction R_{S} for controlling vertical modes of the electromagnetic laser radiation L, a lateral structure 37 for controlling lateral modes of the electromagnetic laser radiation L in the lateral direction R_{LA} can also be introduced into the facet 19.

FIG. 19 shows schematically the theoretical profile of a zero order lateral mode M_{L0} (lateral fundamental mode) of the electromagnetic laser radiation L and a first order lateral mode M_{L1} of the electromagnetic laser radiation L in the edge-emitting semiconductor laser 18 which is manufactured, for example, using the method according to FIGS. 17 and 18. The lateral fundamental mode M_{L0} of the electromagnetic laser radiation L overlaps with the lateral structures 37 which are formed by the etchings 17 in the facet 19. As a result, the lateral fundamental mode M_{L0} is scattered and does not form or only forms in small proportions in the resonator 24 of the edge-emitting semiconductor laser 18. In contrast, the first order lateral mode M_{L1} of the electromagnetic laser radiation L is not disturbed or only slightly disturbed by the etched lateral structures 37 such that it can form in a lateral waveguide 38.

FIGS. 20 and 21 show further embodiments of the metallic contacts 34 on the main surface of the protrusion 29. The metallic contacts 34 according to FIG. 20 have a rectangular shape in a plan view. In contrast thereto, the metallic contacts 34 on the protrusion 29 according to FIG. 21 initially have a continuous, completely connected base surface, from which two strip-shaped regions extend in the longitudinal direction R_{LO} and taper starting from the side surface 13 of the trench 12. The shapes of the metallic contacts 34 are transferred into the shapes of the recesses 11 during the wet-chemical etching.

In the method according to the example embodiment of FIG. 22, a mask 39 which is formed, for example, from metal or else from an absorbing dielectric, such as, for example, silicon or germanium or a mixture of these materials, is applied to the protrusion 29 which forms the ridge waveguide 28 in the finished edge-emitting semiconductor laser 18. The wafer composite 2 comprising the introduced trenches 12 is in turn introduced into an alkaline etching medium 35. During the etching in the alkaline etching medium 35, the epitaxial semiconductor layer sequence 1 is irradiated with electromagnetic radiation UV from the ultraviolet spectral range. As a result, charge carriers which lead to an intensified etching of the epitaxial semiconductor layer 4′ to be etched are induced in those parts of the active region 5 which are not covered by the mask 39. A lateral structure 37 in the facet 19 can also be achieved in this way.

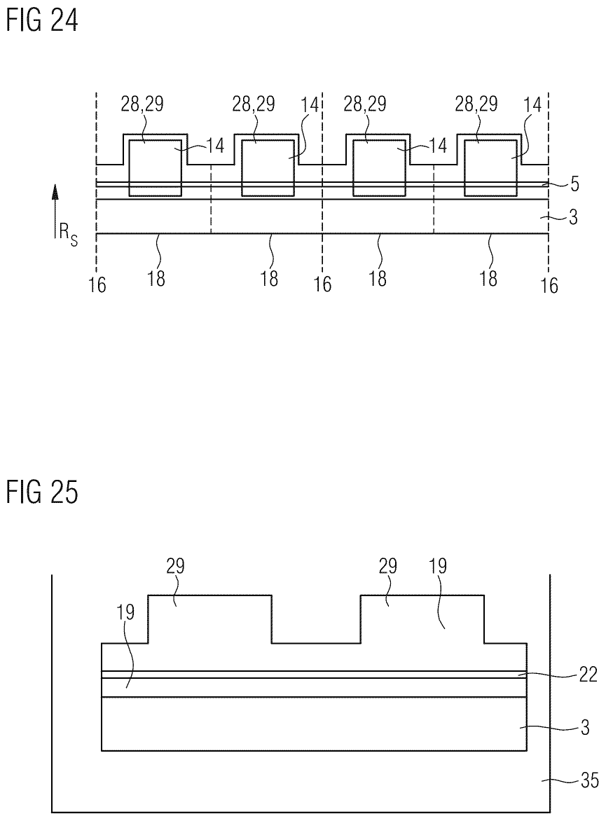

In the method according to the example embodiment of FIGS. 23 to 26, a wafer composite 2 comprising a plurality of edge-emitting semiconductor lasers 18 is provided (FIG. 23). The wafer composite 2 is singulated into separated laser components comprising at least two edge-emitting semiconductor lasers 18, for example by breaking and scribing (FIG. 24). In this case, the edge-emitting semiconductor lasers 18 comprise epitaxial semiconductor layer stacks 14 laterally confined by facets 19 and comprising a plurality of epitaxial semiconductor layers 4 stacked on top of each other in a stacking direction R_{S}. Furthermore, the epitaxial semiconductor layer stacks 14 comprise protrusions 29 which serve as ridge waveguides 28. In a next step, vertical structures 15 are introduced into the facets 19 of the edge-emitting semiconductor lasers 18 in a stacking direction R_{S} by etching in an etching medium 35 (FIG. 25), as already described.

The laser component according to the example embodiment of FIG. 26 can be manufactured, for example, using the method as described with reference to FIGS. 23 to 25. In particular, vertical structures 15 in facets 19 of the two edge-emitting semiconductor lasers 18 are formed in the same way.

In contrast thereto, facets 19 of the edge-emitting semiconductor lasers 18 of the laser component according to the example embodiment of FIG. 27 are treated differently, such that different vertical structures 15 are generated in the facets 19 in the stacking direction R_{S}. This can be achieved by a suitable selection of the parameters described above during the etching, such as the energization or illumination. Thus, different edge-emitting semiconductor lasers 18 with different emission properties can be realized in a laser component.

In the method according to the example embodiment of FIG. 28, in contrast to the method according to the example embodiment of FIGS. 17 and 18, not only is a voltage U applied between the metallic contacts 34 on the protrusions 29 of the epitaxial semiconductor layer stacks 14 and the electrode 36 in the etching medium 35, but an irradiation with ultraviolet light UV takes place simultaneously.

The invention is not restricted to the example embodiments by the description on the basis of said example embodiments. Rather, the invention comprises any novel feature and also any combination of features, which in particular includes any combination of features in the claims, even if this feature or this combination itself is not explicitly specified in the claims or example embodiments.

### LIST OF REFERENCES

1 epitaxial semiconductor layer sequence
2 wafer composite
3 substrate
4, 4′, 4″ epitaxial semiconductor layer
5 active region
6 n-doped waveguide layer
7 p-doped waveguide layer
8 n-doped cladding layer
9 p-doped cladding layer
10 electrical contact layer
11 recess
12 trench
13 side surface
14 epitaxial semiconductor layer stack
15 vertical structure
16 separation line
17 etching
18 edge emitting semiconductor laser
19 facet
20 lower reflecting layer
21 radiation exit region
22 active zone
23 highly reflective layer
24 resonator
25 optical axis
26 metallic contact layer
27 protrusion of substrate
28 ridge waveguide
29 protrusion
30 vertical waveguide
31 p-doped region
32 n-doped region
33, 33′ porous semiconductor material
34 metallic contact
35 etching medium
36 electrode
37 lateral structure
38 lateral waveguide
39 mask
R_{S} stacking direction
L electromagnetic laser radiation
R_{LO} longitudinal direction
R_{LA} lateral direction
A detail
M_{V0} zero order vertical mode
M_{V1} first order vertical mode
M_{V2} second order vertical mode
U voltage
M_{L0} zero order lateral mode
M_{L1} first order lateral mode
UV electromagnetic radiation

1. An edge emitting semiconductor laser comprising:
an epitaxial semiconductor layer stack comprising a plurality of epitaxial semiconductor layers stacked on top of each other over a substrate in a stacking direction, wherein
the epitaxial semiconductor layer stack comprises an active zone in which electromagnetic laser radiation is generated during operation,
the epitaxial semiconductor layer stack comprises at least one facet laterally confining the epitaxial semiconductor layer stack, and
the facet comprises a vertical structure in the stacking direction influencing at least one vertical mode of the electromagnetic laser radiation, wherein the vertical structure comprises at least one recess in the stacking direction and the recess is arranged between a waveguide layer of the epitaxial semiconductor layer stack and the substrate on a side of the waveguide layer facing away from the active zone,
wherein the active zone does not comprise a recess and the substrate has a protrusion with respect to the epitaxial semiconductor layer stack.

2. The edge emitting semiconductor laser according to claim 1, wherein
the vertical structure is arranged at least partially overlapping in the stacking direction with a radiation exit region of the edge-emitting semiconductor laser.

3. The edge emitting semiconductor laser according to claim 1, wherein
the vertical structure comprises two or more recesses in the stacking direction having different depths in a longitudinal direction.

4. The edge emitting semiconductor laser according to claim 1, wherein
the recess is formed by an etching of one of the epitaxial semiconductor layers starting from the facet.

5. The edge emitting semiconductor laser according to claim 4, wherein
the epitaxial semiconductor layers of the epitaxial semiconductor layer stack comprise a III/V compound semiconductor material according to the formula InₓAl_{y}Ga_{1-x-y}GV with 0≤x≤1, 0≤y≤1 and x+y≤1, wherein GV is an element of the fifth main group of the periodic table, and
the epitaxial semiconductor layers with the etching comprise a higher aluminum content and/or a higher indium content than at least one of the directly adjacent epitaxial semiconductor layers.

6. The edge emitting semiconductor laser according to claim 1, wherein the epitaxial semiconductor layer with the etching is n-doped and comprises a higher doping than at least one of the directly adjacent epitaxial semiconductor layers.

7. The edge emitting semiconductor laser according to claim 6, wherein the recess is arranged in an n-doped cladding layer of the epitaxial semiconductor layer stack.

8. The edge emitting semiconductor laser according to claim 1, wherein the recess is confined in a lateral direction.

9. The edge emitting semiconductor laser according to claim 8, wherein the recess has a variable width in a longitudinal direction.

10. The edge emitting semiconductor laser according to claim 1, wherein the recess is completely or partially filled with a porous semiconductor material.

11. A laser component comprising at least two edge emitting semiconductor lasers comprising:
an epitaxial semiconductor layer stack comprising a plurality of epitaxial semiconductor layers stacked on top of each other over a substrate in a stacking direction, wherein
the epitaxial semiconductor layer stack comprises an active zone in which electromagnetic laser radiation is generated during operation,
the epitaxial semiconductor layer stack comprises at least one facet laterally confining the epitaxial semiconductor layer stack, and
the facet comprises a vertical structure in the stacking direction influencing at least one vertical mode of the electromagnetic laser radiation, wherein
the vertical structure comprises at least one recess in the stacking direction and the recess is arranged between a waveguide layer of the epitaxial semiconductor layer stack and the substrate on a side of the waveguide layer facing away from the active zone, wherein the active zone does not comprise a recess and the substrate has a protrusion with respect to the epitaxial semiconductor layer stack.

12. A method of manufacturing a plurality of edge emitting semiconductor lasers comprising:
providing an epitaxial semiconductor layer sequence over a substrate, the epitaxial semiconductor layer sequence comprising a plurality of epitaxial semiconductor layers stacked on top of each other in a stacking direction, wherein the epitaxial semiconductor layer sequence comprises an active region in which electromagnetic radiation is generated during operation,
generating one or more trenches in the epitaxial semiconductor layer sequence,
generating vertical structures in side surfaces of the trenches in the stacking direction, wherein the vertical structures in the side surfaces of the trenches are recesses formed by selectively etching at least one epitaxial semiconductor layer starting from the side surfaces of the trenches and the recesses are arranged between a waveguide layer of the epitaxial semiconductor layer stack and the substrate on a side of the waveguide layer facing away from the active zone, wherein no recess is formed in the active zones.

13. The method according to claim 12, wherein an electrical voltage is applied to the epitaxial semiconductor layer sequence during the selective etching of the at least one epitaxial semiconductor layer.

14. The method according to claim 12, wherein partial regions of the epitaxial semiconductor layer sequence are irradiated with electromagnetic radiation during the selective etching.

15. (canceled)
